(19) United States
(12) Patent Application Publication
(10) Pub. No.: US 2026/0206509 A1
(43) Pub. Date: Jul. 16, 2026

(54) METHOD OF TREATING THIN FILMS AND METHOD OF MANUFACTURING MEMORY DEVICE

(71) Applicant: EGTM Co., Ltd., Suwon-si (KR)

(72) Inventors: Kyu Ho CHO, Suwon-si (KR); Myeong Il KIM, Suwon-si (KR); Ha Na KIM, Suwon-si (KR); Hyun Ju JUNG, Suwon-si (KR); Ju Hwan JEONG, Suwon-si (KR); Hyeon Sik CHO, Suwon-si (KR); Jae Min KIM, Suwon-si (KR); Sun Young BAIK, Suwon-si (KR)

(21) Appl. No.: 19/448,017

(22) Filed: Jan. 13, 2026

(30) Foreign Application Priority Data
Jan. 13, 2025 (KR) 10-2025-0005088
Jan. 7, 2026 (KR) 10-2026-0002610

(51) Int. Cl. H10P 50/26

(52) U.S. Cl. CPC H10P 50/269

(57) ABSTRACT

According to an embodiment of the present invention, a thin film processing method comprises: supplying a surface modifier to an interior of a chamber in which a substrate having a thin film formed thereon is placed; purging the interior of the chamber; supplying an etchant to the interior of the chamber; and purging the interior of the chamber.

### CROSS-REFERENCE TO RELATED APPLICATION

This application claims priority to and the benefit of Korean Patent Application No. 10-2025-0005088, filed on Jan. 13, 2025, and Korean Patent Application No. 10-2026-0002610, filed on Jan. 7, 2026, the disclosure of which is incorporated herein by reference in its entirety.

### BACKGROUND

### 1. Technical Field

The present invention relates to a thin film processing method and a method of manufacturing a memory device including the same, and more particularly, to a method of processing ultra-fine thin films using a surface modifier and an etchant, and a method of manufacturing a memory device including the same.

### 2. Related Art

As miniaturization of semiconductor devices accelerates, there is a need for thinner and more uniform deposition of metal nitride films that are actively used as electrode materials, electrodes, barriers, liners, or gate electrodes in semiconductor devices. In this regard, research is being conducted in various directions, among which research on depositing metal nitride films with island growth characteristics at uniform and thin thicknesses is attracting attention.

Metal nitride films generally have a problem of relatively rough thin film surfaces due to island growth characteristics. In particular, while metal nitride films have uniform stability inside the bulk, they exhibit high surface energy at the surface, and island growth characteristics are significantly manifested due to the tendency to maximize internal bonding, resulting in rough surfaces. In addition, metal nitride films have limitations in that atomic rearrangement occurs easily due to weak directionality of metal bonding, but the strength of metal bonding is strong, so they easily change to a crystalline phase and the grain size increases. As a result, according to the prior art, metal nitride films had limitations in that they had poor surface roughness characteristics and were difficult to deposit thinly, which additionally caused deterioration of interfacial properties during subsequent film deposition.

Meanwhile, conventional atomic layer etching methods have been performed using etchants such as hydrogen fluoride (HF) and hydrogen chloride (HCl), which facilitate modification of the surface layer due to their strong reactivity. However, although the etchants used in conventional etching methods have the advantage of strong reactivity, they have problems in that the etching rate cannot be precisely controlled according to the input amount or it is difficult to selectively etch only very thin thicknesses. The etching amount varies greatly even with minute changes in process conditions, and the etching reaction is difficult to control in a self-limiting manner, making precise etching at the atomic layer level difficult. In addition, since conventional etchants react non-selectively due to high reactivity, etching may be locally concentrated or occur non-uniformly, and in fine pattern processes with complex structures, they caused an increase in surface roughness. Furthermore, atoms (e.g., F, Cl) constituting conventional etchants are very small in size, so they penetrate into undesired lower regions and cause damage, thereby deteriorating the electrical characteristics of the device.

Accordingly, in order to effectively improve the surface roughness of metal nitride films with island growth characteristics and to implement ideal Atomic Layer Etch (ALE), which is the opposite concept of Atomic Layer Deposition (ALD), there is a need for development and research on thin film processing technology using a new etchant that can maintain a constant etched thickness through termination of surface reactions and precisely control the etching rate.

### SUMMARY

An object of the present invention is to provide a thin film processing method with thin and uniform thickness and a method of manufacturing a memory device including the same.

An object of the present invention is to provide a thin film processing method capable of effectively improving the surface roughness of metal nitride films having island growth characteristics.

An object of the present invention is to provide a thin film processing method capable of preventing deterioration of interfacial properties during subsequent film deposition through improvement of surface roughness of metal nitride films.

An object of the present invention is to provide a thin film processing method capable of precisely controlling the etching rate and enabling uniform etching at the atomic layer level by using an etchant having self-limiting reaction characteristics.

An object of the present invention is to provide a thin film processing method capable of minimizing damage to lower regions and preventing deterioration of electrical characteristics of devices through selective and controllable etching, unlike conventional highly reactive etchants.

The problems to be solved by the present invention are not limited to the above-mentioned problems, and problems not mentioned will be clearly understood by those skilled in the art to which the present invention belongs from the present specification and the accompanying drawings.

According to an embodiment of the present invention, a thin film processing method comprises: supplying a surface modifier to an interior of a chamber in which a substrate having a thin film formed thereon is placed; purging the interior of the chamber; supplying an etchant to the interior of the chamber; and purging the interior of the chamber, wherein the etchant is represented by any one of the following <Formula 1>, <Formula 2>, and <Formula 3>:

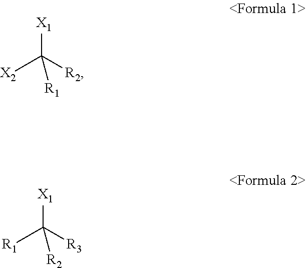

In the <Formula 1> or <Formula 2>, X1 to X2 may each be the same or different from each other, and are independently selected from hydrogen, chlorine element, and chloroalkyl group having 1 to 5 carbon atoms, R1 to R3 may each be the same or different from each other, and are independently selected from hydrogen, linear, branched, or cyclic alkyl group having 1 to 5 carbon atoms, aryl group having 6 to 12 carbon atoms, hydroxy group having 0 to 4 carbon atoms, and alkoxy group having 0 to 4 carbon atoms.

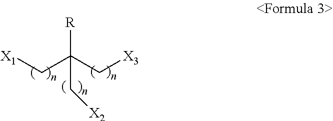

In the <Formula 3>, n is each independently selected from integers of 0 to 5, X1 to X3 are each independently selected from alkoxy group having 1 to 5 carbon atoms and dialkylamino group having 1 to 5 carbon atoms, and R is selected from hydrogen, linear, branched, or cyclic alkyl group having 1 to 5 carbon atoms, alkoxy group having 1 to 5 carbon atoms, and dialkylamino group having 1 to 5 carbon atoms.

The etchant may be any one of Dichloromethyl methyl ether (DCMME), 1-chloromethyl ethyl ether (1-CMEE), Dimethylformamide dimethyl acetal (DFDA), and Tris(dimethylamino)methane (TDMAM).

The method may further comprise, before the step of supplying the surface modifier, forming the thin film on the substrate by Atomic Layer Deposition (ALD).

The thin film may be a metal nitride thin film having a Group 4 metal as a central element.

The Group 4 metal may be any one of Titanium (Ti), Zirconium (Zr), and Hafnium (Hf).

The thin film may be a metal nitride thin film having a Group 5 metal as a central element.

The Group 5 metal may be any one of Vanadium (V), Niobium (Nb), and Tantalum (Ta).

The thin film may be a metal film or metal nitride thin film having a Group 6 metal as a central element.

The Group 6 metal may be any one of Molybdenum (Mo) and Tungsten (W).

The surface modifier may be any one of O₃, O₂, H₂O, and H₂O₂.

According to an embodiment of the present invention, a method of manufacturing a memory device may include the thin film processing method described above.

The technical solutions of the present invention are not limited to the above-mentioned solutions, and solutions not mentioned will be clearly understood by those skilled in the art to which the present invention belongs from the present specification and the accompanying drawings.

According to the thin film processing method according to an embodiment of the present invention, a thin film with thin and uniform thickness can be formed using a surface modifier and an etchant.

According to the thin film processing method according to an embodiment of the present invention, the etching rate can be precisely controlled using an etchant having self-limiting reaction characteristics. This solves the difficulty in controlling the etching rate that conventional highly reactive etchants had and enables precise thickness control at the atomic layer level.

According to the thin film processing method according to an embodiment of the present invention, it can be effectively applied not only to metal nitride films but also to oxide films and metal films having various transition metals of Groups 4 to 6 as central elements, thereby providing versatility that can be utilized in a wide range of semiconductor device manufacturing processes.

The effects of the present invention are not limited to the above-mentioned effects, and effects not mentioned will be clearly understood by those skilled in the art to which the present invention belongs from the present specification and the accompanying drawings.

### BRIEF DESCRIPTION OF DRAWINGS

FIG. 1 is a diagram illustrating a thin film processing method according to an embodiment of the present invention.

FIG. 2 is a graph schematically illustrating a supply cycle according to an embodiment of the present invention.

FIG. 3 is a graph schematically illustrating a supply cycle according to a comparative example.

FIGS. 4 to 6 are diagrams showing the thickness and roughness of a TiN thin film, before etching/according to the comparative example/according to Experimental Example 1.

FIG. 7 is a graph analyzing the thickness of a thin film according to whether or not an etchant is supplied for each process temperature according to Experimental Example 2.

FIG. 8(a) is a graph showing EPC according to the number of cycles according to Experimental Example 3. FIG. 8(b) is a graph showing EPC according to the etchant supply amount according to Experimental Example 3.

FIG. 9 is a diagram showing the thickness and roughness of a TiN thin film before etching/after etching according to Experimental Example 4.

FIG. 10 is a diagram showing the thickness and roughness of a TiN thin film, before etching/after etching according to Experimental Example 5.

FIG. 11(a) is a graph showing EPC according to the number of cycles according to Experimental Example 6. FIG. 11(b) is a graph showing EPC according to the etchant supply amount according to Experimental Example 6.

FIG. 12 is a graph showing the thickness of a thin film according to the number of cycles for each metal nitride film according to Experimental Example 7.

FIG. 13 is a graph showing the change in thickness of a thin film according to etching.

### DESCRIPTION OF EXAMPLE EMBODIMENTS

The above-described objects, features, and advantages of the present invention will become more apparent through the following detailed description in connection with the accompanying drawings. However, since the present invention may have various modifications and several embodiments, specific embodiments will be illustrated in the drawings and described in detail below.

Throughout the specification, like reference numerals refer in principle to like elements. In addition, components having the same function within the scope of the same concept appearing in the drawings of each embodiment are described using the same reference numerals, and redundant descriptions thereof will be omitted.

If it is determined that a detailed description of a known function or configuration related to the present invention may unnecessarily obscure the gist of the present invention, the detailed description thereof will be omitted. In addition, numerals (for example, first, second, etc.) used in the description process of the present specification are merely identification symbols for distinguishing one component from another component.

In the following embodiments, singular expressions include plural expressions unless the context clearly dictates otherwise.

In the following embodiments, terms such as “comprise” or “have” mean that a feature or component described in the specification exists, and do not preclude the possibility of adding one or more other features or components.

In the drawings, components may be exaggerated or reduced in size for convenience of description. For example, the size and thickness of each component shown in the drawings are arbitrarily shown for convenience of description, and the present invention is not necessarily limited to what is shown.

Where an embodiment can be implemented differently, the order of specific processes may be performed differently from the order described. For example, two processes described in succession may be performed substantially simultaneously, or may be performed in an order opposite to the order described.

The present invention relates to a method of depositing a thin film with island growth, particularly a metal nitride thin film, at a uniform and thin thickness. Island growth refers to growth in an island form when depositing a thin film on a substrate, and thin films growing in an island form generally have rough surface characteristics and are difficult to deposit as fine thin films.

The present invention relates to a method of making an island-grown thin film into a thin and uniform thin film through an Atomic Layer Etch (ALE) process, and the surface roughness of the thin film can be improved through the atomic layer etching process.

The principle by which surface roughness is improved according to the present invention is as follows. In the case of protruding portions on the surface, they have higher surface energy than flat portions and also have a wider exposure range. In addition, since they are less affected by surrounding atoms, when a surface modifier is introduced, modification of the protruding portions proceeds more than portions that are not protruding. Conversely, in the case of portions recessed inward from the surface, they have lower surface energy due to inverse curvature, and since they are more affected by surrounding atoms, modification proceeds less. The more modification has proceeded, the more etching occurs when an etchant is introduced, and the protruding portions gradually decrease. Therefore, when an atomic layer etching process (ALE) is performed on a thin film, surface roughness can be improved.

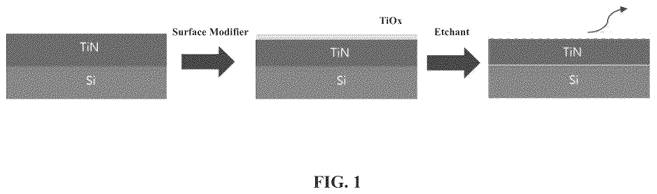

Hereinafter, the thin film processing method according to the present invention will be described in more detail with reference to FIGS. 1 to 13.

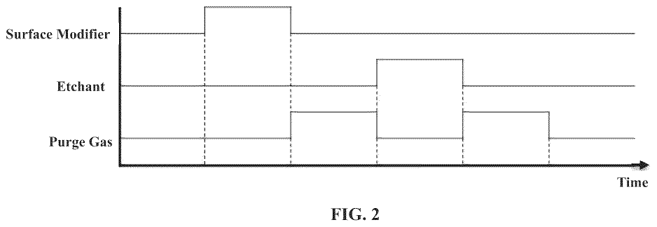

FIG. 1 is a diagram illustrating a thin film processing method according to an embodiment of the present invention, and FIG. 2 is a graph schematically illustrating a supply cycle according to an embodiment of the present invention. A substrate is loaded into the interior of a process chamber, and the substrate has a thin film formed on a surface thereof. The thin film is formed by Atomic Layer Deposition (ALD), and may be formed after being loaded into the interior of the process chamber or may be loaded into the interior of the process chamber after the thin film is formed.

According to one example, the substrate may be a silicon (Si) substrate, and the thin film may be a metal nitride film, a metal oxide film, and/or a metal film deposited on the substrate by ALD.

The thin film may be deposited through island growth during the formation process.

According to one embodiment, the thin film may be a metal nitride thin film, a metal oxide thin film, and/or a metal film having a Group 4 metal as a central element, and may have one of Ti, Zr, and Hf as a central element.

According to one embodiment, the thin film may be a metal nitride thin film, a metal oxide thin film, and/or a metal film having a Group 5 metal as a central element, and may have one of V, Nb, and Ta as a central element.

According to one embodiment, the thin film may be a metal nitride thin film, a metal oxide thin film, and/or a metal film having a Group 6 metal as a central element, and may have one of Mo and W as a central element.

Meanwhile, the following process conditions may be adjusted. The process conditions may include temperature of the substrate or process chamber, chamber pressure, and gas flow rate.

Referring again to FIGS. 1 and 2, the substrate may be exposed to a surface modifier supplied to the interior of the chamber, and the surface modifier may be any one of O₃, O₂, H₂O, and H₂O₂. The surface modifier may react with the thin film, particularly the metal nitride film, to modify the surface of the metal nitride film. At this time, as described above, protruding portions due to island growth have high surface energy compared to surrounding portions and thus have high reactivity, and due to high curvature, they are relatively less affected by surrounding atoms, so the possibility of collision with the surface modifier increases and they can react relatively more with the surface modifier.

After supplying the surface modifier, a purge gas (for example, an inert gas such as nitrogen (N₂), argon (Ar), and/or helium (He)) is supplied to the interior of the chamber, so that unreacted materials or by-products can be removed or purified.

After supplying the surface modifier (preferably, after supplying the surface modifier and supplying the purge gas), an etchant may be supplied to the interior of the chamber, and the thin film (metal nitride film) modified through the surface modifier may be exposed to the etchant. The protruding portions of the thin film modified through the surface modifier have lower thin film density compared to non-protruding portions, so the reaction with the etchant occurs relatively well and relatively more etching can be performed. Through this, the surface roughness due to the protruding portions of the metal nitride film can be improved.

The etchant according to one embodiment may be represented by <Formula 1> or <Formula 2>.

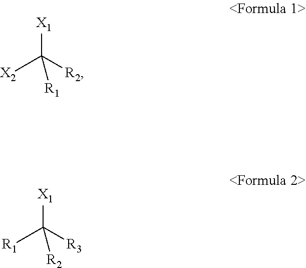

In the <Formula 1> or <Formula 2>, X1 to X2 may each be the same or different from each other, and are independently selected from hydrogen, chlorine element, and chloroalkyl group having 1 to 5 carbon atoms, R1 to R3 may each be the same or different from each other, and may be independently selected from hydrogen, linear, branched, or cyclic alkyl group having 1 to 5 carbon atoms, aryl group having 6 to 12 carbon atoms, hydroxy group having 0 to 4 carbon atoms, and alkoxy group having 0 to 4 carbon atoms.

According to one embodiment, the etching initiator (or etchant) may be any one of Dichloromethyl methyl ether (DCMME) and 1-Chloromethyl ethyl ether (1-CMEE).

Alternatively, the etchant may be represented by <Formula 3>.

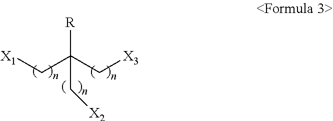

In the <Formula 3>, n is each independently selected from integers of 0 to 5, X1 to X3 are each independently selected from alkoxy group having 1 to 5 carbon atoms and dialkylamino group having 1 to 5 carbon atoms, and R may be selected from hydrogen, linear, branched, or cyclic alkyl group having 1 to 5 carbon atoms, alkoxy group having 1 to 5 carbon atoms, and dialkylamino group having 1 to 5 carbon atoms.

Specifically, the etchant may be any one of Dimethylformamide dimethyl acetal (DFDA) and Tris(dimethylamino)methane (TDMAM).

Referring again to FIG. 2, after supplying the etchant, a purge gas (for example, an inert gas such as Ar) is supplied to the interior of the chamber, so that unreacted materials or by-products can be removed or purified.

According to one embodiment of the present invention, the source for the ALE process may be supplied through a Liquid Flow Meter (LFM) method. The LFM method is a method in which a liquid source is quantitatively metered and supplied to a vaporizer, and then vaporized and introduced into a reaction chamber. Specifically, the liquid source is precisely controlled at a preset flow rate through a flow meter (LFM), and the source can be instantaneously vaporized in a heated vaporizer, mixed with a carrier gas, and then supplied into the process chamber.

According to one embodiment of the present invention, the source for the ALE process may be supplied through a vapor method. The vapor method is a method in which a source is heated in a storage container (canister) to make it into a vapor state, and then the vapor is directly supplied to the reaction chamber. Specifically, the source is naturally vaporized in a storage container maintained at a predetermined temperature, and the generated source vapor is moved to the reaction chamber by a carrier gas or pressure difference. At this time, the source supply amount may be mainly determined by the vapor pressure of the source, the storage container temperature, and the carrier gas flow rate. A metering valve may be included to precisely control the supply flow rate of the source vapor. At this time, the flow rate of the source vapor can be controlled by adjusting the opening degree of the metering valve disposed on the supply line.

Hereinafter, the configuration and effects of the present invention will be described in more detail with specific examples, but these examples are merely for a clearer understanding of the present invention and are not intended to limit the scope of the present invention.

### (1) Example 1

### Comparative Example

A substrate having an island-grown thin film (TiN) formed thereon was prepared, and after measuring the thickness and roughness of the thin film, etching was performed using an etchant without using a surface modifier. 1-chloromethyl ethyl ether (1-CMEE) (represented by <Formula 4> below) was used as the etchant, and etching was performed at a process temperature of 300° C.

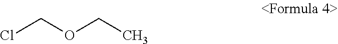

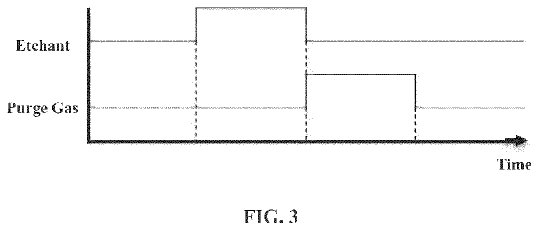

FIG. 3 is a graph schematically illustrating a supply cycle according to the comparative example.

The etching process was repeated 50 times with the following process as one cycle, referring to FIG. 3.
1) Supply etchant (1-CMEE) into the reaction chamber
2) Supply purge gas (Ar gas) into the reaction chamber to remove unreacted materials or by-products

This comparative example was performed under conditions using only an etchant, in order to explain a state where the ALE process is not established when only an etchant is used.

### Experimental Example 1

A substrate having an island-grown thin film (TiN) formed thereon was prepared, and etching was performed by sequentially supplying a surface modifier and an etchant. 03 was used as the surface modifier, 1-chloromethyl ethyl ether (1-CMEE) was used as the etchant, and etching was performed at a process temperature of 300° C.

The etching process was repeated 50 times with the following process as one cycle, referring to FIG. 2.
1) Supply surface modifier (O₃) into the reaction chamber
2) Supply purge gas (Ar gas) into the reaction chamber to remove unreacted materials or by-products
3) Supply etchant (1-CMEE) into the reaction chamber
4) Supply purge gas (Ar gas) into the reaction chamber to remove unreacted materials or by-products

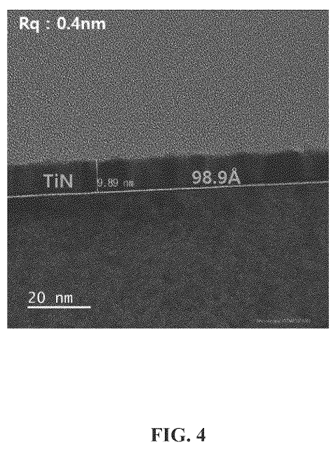

FIGS. 4 to 6 are diagrams showing the thickness and roughness of TiN thin films before etching/according to the comparative example/according to Experimental Example 1, respectively, where the thickness was measured using a Transmission Electron Microscope (TEM), and the roughness was measured using an Atomic Force Microscope (AFM) analyzer.

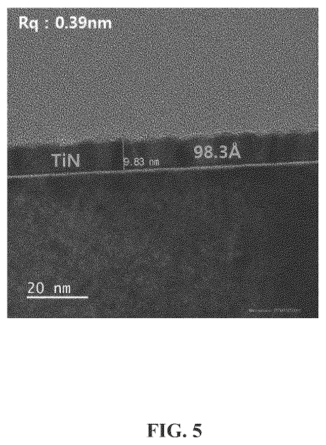

Referring to FIGS. 4 and 5, when the surface modifier was not used, the thickness due to etching decreased by only about 0.6 Å from 98.9 Å before etching to 98.3 Å, showing a small reduction, and the Rq value for roughness was not improved from 0.4 nm before etching to 0.39 nm, confirming that the ALE process was not established. The changes in thin film thickness and Rq value according to FIGS. 4 and 5 are values within the measurement error range, indicating that there is virtually no reduction.

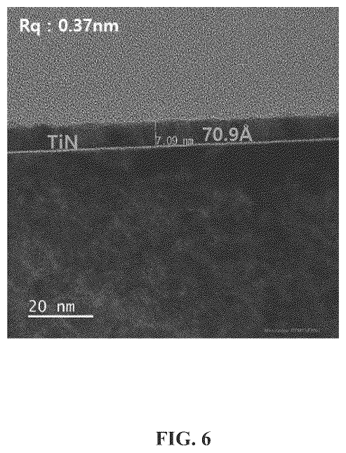

On the other hand, referring to FIGS. 4 and 6, the thickness of the thin film decreased by about 30 Å from 98.9 Å before etching to 70.9 Å, and the Rq value (Root Mean Square roughness, the lower the value, the more uniform the surface) decreased from 0.4 nm before etching to 0.37 nm, confirming that the roughness was relatively greatly improved, and referring to the TEM data, it was confirmed that the roughness was improved enough to be visually confirmed.

When the surface roughness is poor, differences in electrical characteristics occur between thin and thick portions of the thin film, and in particular, as semiconductor devices become miniaturized and the absolute thickness of the thin film becomes thinner, relative thickness deviation becomes greater, which can adversely affect the performance uniformity and reliability of the device. Therefore, by improving surface roughness, uniformity of thin film thickness can be secured, and through this, the quality of interfaces formed in subsequent processes can be improved to enhance the electrical characteristics and yield of devices. Through these results, it was found that a surface modifier is necessary for the etching process of TiN thin films, and it was confirmed that the ALE process is established by applying the surface modifier.

### (2) Example 2

### Experimental Example 2 (Evaluation of Etching Characteristics According to Temperature)

In Experimental Example 2, 1-chloromethyl ethyl ether (1-CMEE) was used as an etchant, and TiN thin films were etched in a process temperature range of 300° C. to 380° C. to confirm etching characteristics according to temperature.

Sources were cyclically fed into the chamber according to the supply cycle of FIG. 2, and O₃ was used as a surface modifier. After performing 50 cycles of the etching process at each temperature condition of 300° C., 340° C., and 380° C., changes in thin film thickness were measured. Specifically, the process of surface modifier supply (3 seconds)→purge gas supply (15 seconds)→etchant supply (60 seconds)→purge gas supply (30 seconds) was repeated 50 times as one cycle. At this time, Ar gas was used as the purge gas.

In addition, in order to compare with the case where a surface modifier was not used, according to the supply cycle of FIG. 3, only the etchant (1-CMEE) was cyclically fed without supplying a surface modifier. Similarly, after performing 50 cycles of the etching process at each temperature condition of 300° C., 340° C., and 380° C., changes in thin film thickness were measured. Specifically, when a surface modifier was not used, the process of etchant supply (60 seconds)→purge gas supply (30 seconds) was repeated 50 times as one cycle. At this time, Ar gas was used as the purge gas.

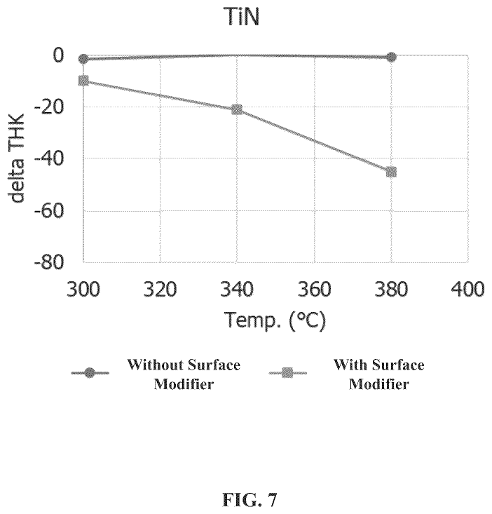

FIG. 7 is a graph analyzing the thickness of thin films according to whether or not an etchant is supplied for each process temperature according to Experimental Example 2.

Referring to FIG. 7, when only the etchant was repeatedly supplied without using a surface modifier, almost no etching occurred in all temperature ranges, and the change in thin film thickness showed a value close to 0. On the other hand, when a surface modifier was used, a reduction in thin film thickness of about 10 Å at 300° C., about 20 Å at 340° C., and about 45 Å at 380° C. was confirmed. This shows that the thin film thickness decreases linearly as the process temperature increases.

Through these results, it was confirmed that thin films at the atomic layer level can be uniformly etched through surface reactions between the surface modifier and the etchant, and it was found that the etching rate can be controlled by adjusting the process temperature. In addition, it was reconfirmed that the use of a surface modifier is essential for the establishment of the ALE process.

The principle by which etching performance is improved when a surface modifier is used is expected to be as follows. The surface modifier in the form of an oxidizing agent (e.g., O₃) used in the modification step reacts with the surface of the film to be etched to change the chemical bonding state and composition of the surface. The surface of the nitride film has a bonding structure mainly including nitrogen species or —NH terminals, and oxygen species bonded by the oxidizing agent have higher reactivity than nitrogen species, facilitating initiation of reactions in the subsequent etching step. For example, in the case of TiN thin films, surface oxidation can proceed with a reaction equation such as TiN(s)+3 O₃(g)→TiO₂(s)+NO(g)+3O₂(g), through which the surface after the modification step can be converted to a state more suitable for etching reactions.

In addition, during the modification process using a surface modifier in the form of an oxidizing agent, the center metal in the underlying metal film or metal nitride film bonds with oxygen, thereby increasing the oxidation state, and this increase in oxidation state lowers the electron density of the center metal and can promote reactions with subsequent etchants. Importantly, this modification step changes only the outermost surface region of the film to be etched, and only the modified surface layer participates in the etching reaction in subsequent processes, thereby maintaining the self-limiting characteristics of the ALE process.

### Experimental Example 3 (EPC Evaluation)

In Experimental Example 3, 1-chloromethyl ethyl ether (1-CMEE) was used as an etchant and O₃ was used as a surface modifier to etch a TiN thin film at a process temperature of 300° C. As in Experimental Example 1, the etching process was repeatedly performed according to the supply cycle of FIG. 2 while evaluating changes in EPC (Etch Per Cycle) according to the number of cycles and/or etchant supply amount. Specifically, the process of surface modifier supply (3 seconds)→purge gas supply (15 seconds)→etchant supply (60 seconds)→purge gas supply (30 seconds) was repeated several times as one cycle at a process temperature of 300° C. At this time, Ar gas was used as the purge gas.

First, to confirm the stability of the etching rate according to the number of cycles, the etching process was performed up to a maximum of 60 cycles, and the source was supplied into the chamber at 0.1 g/min through the LFM method.

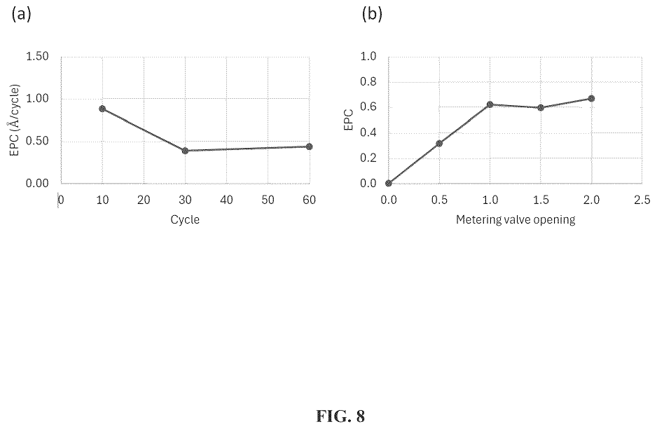

FIG. 8(a) is a graph showing EPC according to the number of cycles according to Experimental Example 3.

In the initial cycles, relatively high EPC values were exhibited, but as the cycles increased to 30 cycles, the EPC also decreased, and thereafter was maintained at a substantially constant level up to 60 cycles. This means that the EPC is maintained stably even when cycles are increased after 30 cycles, and it was confirmed that the etching process proceeds through the atomic layer etching method and the etching rate can be precisely controlled.

In addition, to evaluate saturation characteristics according to the supply amount of the etchant, EPC was measured while varying the metering valve opening value. The source was supplied through the vapor method.

FIG. 8(b) is a graph showing EPC according to the etchant supply amount according to Experimental Example 3.

When the metering valve opening value was 0, no etching occurred, and as the supply amount increased, EPC increased linearly. Thereafter, at a supply amount above a certain level (metering valve opening value: about 1.0), EPC converged to an almost constant value, confirming that the saturation region was reached. This shows that when the etchant supply amount increases sufficiently, the surface reaction becomes saturated and the etching rate no longer increases.

Through these results, it was confirmed that the etching process of the present invention proceeds as an atomic layer etching method having self-limiting characteristics, and reproducibility and uniformity of the process can be secured in the saturation region. This means that, according to the present invention, unlike conventional highly reactive etchants (etchants such as HCl, HF, etc.), the etching rate for thin films can be precisely controlled.

### (3) Example 3

### Experimental Example 4 (Thickness and Rq Evaluation)

In Experimental Example 4, an atomic layer etching process was performed on a TiN nitride film using O₃ as a surface modifier and 1-chloromethyl ethyl ether (1-CMEE) as an etchant. The supply cycle (one cycle) of FIG. 2 was repeated ‘60 times’. Specifically, the process of surface modifier supply (3 seconds)→purge gas supply (15 seconds)→etchant supply (60 seconds)→purge gas supply (30 seconds) was repeated 60 times as one cycle at a process temperature of 300° C. At this time, Ar gas was used as the purge gas, and Transmission Electron Microscopy (TEM) analysis and Atomic Force Microscopy (AFM) analysis were performed before and after the ALE process to confirm changes in the cross-sectional structure and surface roughness of the thin film.

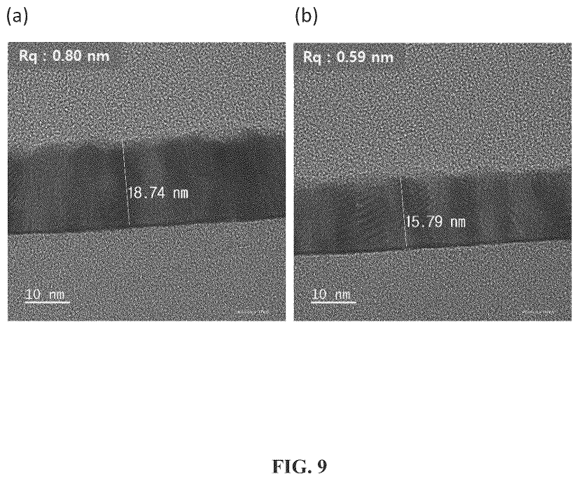

FIG. 9 is a diagram showing the thickness and roughness of a TiN thin film before etching/after etching according to Experimental Example 4. Specifically, FIG. 9(a) is a diagram showing the thickness and surface roughness of a TiN thin film before etching according to Experimental Example 4, and FIG. 9(b) is a diagram showing the thickness and surface roughness of a TiN thin film after etching according to Experimental Example 4.

As a result of TEM/AFM analysis, the thickness of the thin film before the ALE process was measured as 187.4 Å (=18.74 nm), and the Rq (Root Mean Square roughness) value was 0.80 nm. After the ALE process, the thickness of the thin film decreased to 157.9 Å (=15.79 nm), confirming a thickness reduction of about 29.5 Å. In addition, the Rq value decreased to 0.59 nm, confirming that the surface roughness was improved by 26%.

In addition, as a result of visually comparing the TEM images, irregularities on the upper surface of the thin film were clearly observed before the ALE process, but after the ALE process, it was confirmed that the surface became relatively flat and uniform. This visually demonstrates that the atomic layer etching process can effectively improve surface roughness by selectively removing protruding portions of the surface.

Through these results, it was confirmed that the atomic layer etching process (ALE process) using the surface modifier and etchant of the present invention can precisely reduce the thickness of a metal nitride film while simultaneously improving surface roughness. This may contribute to improvement of interfacial properties during subsequent film deposition.

### (4) Example 4 (Etchant: Using Dimethylformamide Dimethyl Acetal (DFDA))

In Example 4, etching was performed by replacing the etchant (1-chloromethyl ethyl ether (1-CMEE)) of Examples 2 and 3 with Dimethylformamide Dimethyl Acetal (DFDA) etchant.

### Experimental Example 5 (Thickness and Roughness Evaluation)

Specifically, in Experimental Example 5, an atomic layer etching process (ALE process) was performed on a TiN nitride film using O₃ as a surface modifier and Dimethylformamide Dimethyl Acetal (DFDA) as an etchant. The process temperature was set at 340° C., and the etching process was performed by repeating the supply cycle (one cycle) of FIG. 2 60 times. Specifically, the process of surface modifier supply (3 seconds)→purge gas supply (15 seconds)→etchant supply (60 seconds)→purge gas supply (30 seconds) was repeated 60 times as one cycle at a process temperature of 340° C. At this time, Ar gas was used as the purge gas.

Transmission Electron Microscopy (TEM) analysis and Atomic Force Microscopy (AFM) analysis were performed before and after the ALE process to confirm changes in the cross-sectional structure and surface roughness of the thin film.

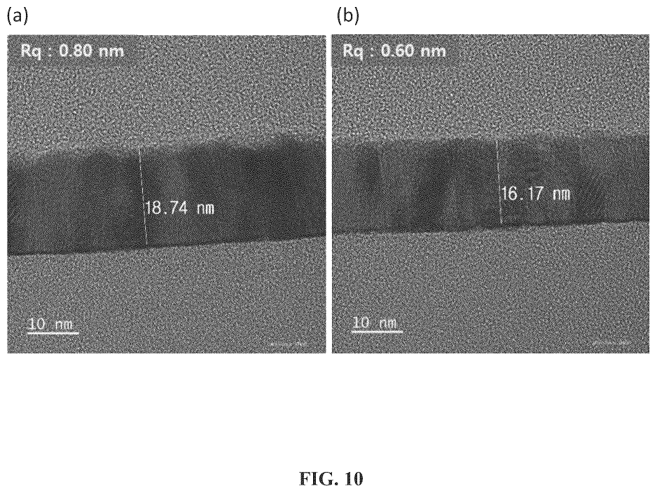

FIG. 10 is a diagram showing the thickness and roughness of a TiN thin film before etching/after etching according to Experimental Example 5. Specifically, FIG. 10(a) is a diagram showing the thickness and surface roughness of a TiN thin film before etching according to Experimental Example 5, and FIG. 10(b) is a diagram showing the thickness and surface roughness of a TiN thin film after etching according to Experimental Example 5.

As a result of TEM and AFM analysis, the thickness of the thin film before the ALE process was measured as 187.4 Å (=18.74 nm), and the Rq (Root Mean Square roughness) value was 0.80 nm. After the ALE process, the thickness of the thin film decreased to 161.7 Å (=16.17 nm), confirming a thickness reduction of about 25.7 Å. In addition, the Rq value decreased to 0.60 nm, confirming that the surface roughness was improved by 25%.

In addition, as a result of visually comparing the TEM images, irregularities on the upper surface of the thin film were clearly observed before the ALE process, but after the ALE process, it was confirmed that the surface became relatively flat and uniform. This visually demonstrates that even when using the ‘DFDA etchant’, the atomic layer etching process can effectively improve surface roughness by selectively removing protruding portions of the surface.

Through these results, it was confirmed that not only when using the 1-CMEE etchant of the present invention but also when using the DFDA etchant, the thickness of a metal nitride film can be precisely reduced while simultaneously effectively improving surface roughness through combination with a surface modifier. In addition, this demonstrates that various etchants having structures similar to 1-CMEE or DFDA can be applied to thin film processing according to the present invention.

### Experimental Example 6 (EPC Evaluation)

In Experimental Example 6, ‘Dimethylformamide Dimethyl Acetal (DFDA)’ was used as an etchant and O₃ was used as a surface modifier to etch a TiN thin film at a process temperature of 340° C. The etching process was repeatedly performed according to the supply cycle of FIG. 2 while evaluating changes in EPC (Etch Per Cycle) according to the number of cycles and/or etchant supply amount. Specifically, the process of surface modifier supply (3 seconds)→purge gas supply (15 seconds)→etchant supply (60 seconds)→purge gas supply (30 seconds) was repeatedly performed several times as one cycle at a process temperature of 340° C. At this time, Ar gas was used as the purge gas.

First, to confirm the stability of the etching rate according to the number of cycles, the etching process was performed up to a maximum of 60 cycles, and the source was supplied into the chamber at 0.1 g/min through the LFM method.

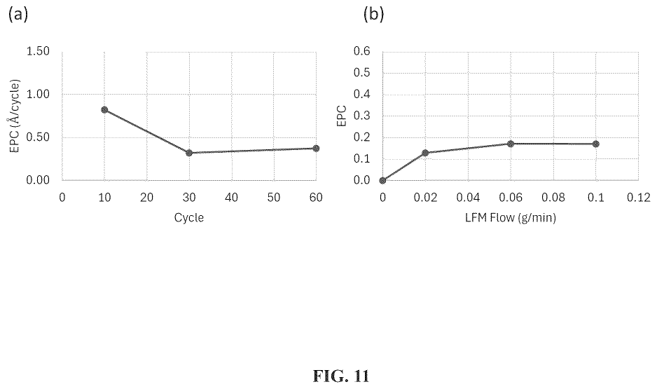

FIG. 11(a) is a graph showing EPC according to the number of cycles according to Experimental Example 6.

In the initial cycles, relatively high EPC values were exhibited, but EPC decreased until reaching 30 cycles, and thereafter was maintained stably at a substantially constant level up to 60 cycles. This means that the EPC is maintained stably even when cycles are increased after 30 cycles, and it was confirmed that even when using the DFDA etchant, the etching process proceeds through the atomic layer etching method and the etching rate can be precisely controlled.

In addition, to evaluate saturation characteristics according to the supply amount of the etchant, EPC was measured while varying the LFM (Liquid Flow Meter) flow value.

FIG. 11(b) is a graph showing EPC according to the etchant supply amount according to Experimental Example 6.

When there was no etchant supply (LFM Flow=0 g/min), no etching occurred, and it was confirmed that EPC increased linearly as the supply amount increased. Thereafter, at a supply amount above a certain level (LFM Flow: supply amount of about 0.02 g/min or more), EPC converged to a substantially constant value, confirming that the saturation region was reached. This shows that when the etchant supply amount increases sufficiently, the surface reaction becomes saturated and the etching rate no longer increases.

Through these results, it was confirmed that not only when using the 1-CMEE etchant of the present invention but also when using the DFDA etchant, the process proceeds as an atomic layer etching method having self-limiting characteristics, and reproducibility and uniformity of the process can be secured in the saturation region. In addition, it was demonstrated that various etchants having structures similar to 1-CMEE or DFDA (i.e., etchants according to Formulas 1 to 3 (e.g., Dichloromethyl methyl ether (DCMME), Tris(dimethylamino)methane (TDMAM))) can be applied to thin film processing according to the present invention, and unlike conventional highly reactive etchants (HCl, HF), by using the etchants the etching rate of thin films can be precisely controlled.

### (5) Example 5 (Etching Evaluation by Metal Nitride Film)

### Experimental Example 7 (Thickness Change Evaluation)

In Experimental Example 7, TiN, TiSiN, and MoN thin films were etched at a process temperature of 340° C. using Dichloromethyl methyl ether (DCMME) as an etchant and O₃ as a surface modifier.

Sources were cyclically fed into the chamber according to each supply cycle of FIGS. 2 and 3, and changes in thin film thickness per cycle when a surface modifier was used and when it was not used were compared and analyzed. The etching process was performed up to a maximum of 100 cycles for each thin film. Specifically, in Experimental Example 7, the process of surface modifier supply (3 seconds)→purge gas supply (15 seconds)→etchant supply (10 seconds)→purge gas supply (10 seconds) was repeatedly performed several times as one cycle at a process temperature of 340° C. At this time, Ar gas was used as the purge gas.

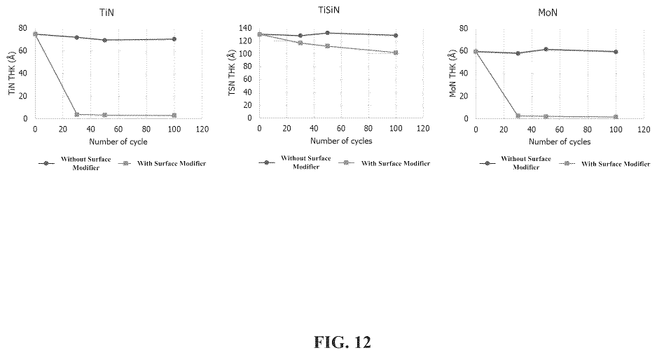

FIG. 12 is a graph showing the thickness of thin films according to the number of cycles for each metal nitride film according to Experimental Example 7.

When only the etchant was repeatedly supplied without using a surface modifier, it was confirmed that the thin film thickness hardly decreased even when the number of cycles increased in all thin films of TIN, TiSiN, and MON, indicating that no etching occurred. That is, when a surface modifier was not used, it was reconfirmed that the ALE process was not established.

On the other hand, when a surface modifier was used, the thin film thickness decreased linearly with increasing number of cycles in all thin films (TIN, TiSiN, MON). Specifically, in the case of the TiN thin film, starting from an initial thickness of about 75 Å, it was almost completely etched after 30 cycles, and the etching rate was measured as 2.27 Å/cycle. In the case of the MON thin film as well, starting from an initial thickness of about 60 Å, it was almost completely etched after 30 cycles, and the etching rate was measured as 1.84 Å/cycle. In the case of the TiSiN thin film, starting from an initial thickness of about 130 Å, it gradually decreased at a relatively slow rate, and the etching rate was measured as 0.28 Å/cycle, showing a relatively lower etching rate compared to other thin films.

Through these results, it was reconfirmed that the sequential surface reaction of the surface modifier and etchant is essential for effective atomic layer etching. In addition, it was confirmed that the thin film processing method according to the present invention can be applied not only when using 1-CMEE and DFDA etchants but also when using the DCMME etchant.

In addition, it was confirmed that the thin film processing method according to the present invention enables precise etching at the atomic layer level for various metal nitride films such as TiN, TiSiN, and MON, and it was found that the etching rate varies depending on the type of thin film, making it applicable to selective etching processes. In particular, it was confirmed that in the case of TiN and MON, rapid thin film removal is possible with high etching rates, and in the case of TiSiN, more precise thickness control is possible with a relatively low etching rate. This demonstrates that the thin film processing method of the present invention has versatility applicable to various metal nitride films.

Through Experimental Examples 1 to 7, it was confirmed that metal nitride films with thin and uniform thickness can be formed by the atomic layer etching (ALE) process using the surface modifier and etchant of the present invention. In particular, it was confirmed that the use of a surface modifier is essential for effective etching, and the etchants represented by Formulas 1, 2, and 3 of the present invention have self-limiting characteristics and enable precise etching at the atomic layer level. In addition, it was confirmed that the method is applicable not only to TiN but also to various metal nitride films such as TiSiN and MoN.

The thin film processing method of the present invention can provide the following expected effects.

First, surface roughness can be effectively improved. As confirmed in Experimental Examples 4 and 5, the surface roughness (Rq) decreased by 25-26% compared to before etching through the atomic layer etching process, which means that protruding portions of the thin film surface were selectively removed and the surface was planarized. The improvement in surface roughness can provide the effect of improving the electrical characteristics and reliability of devices by enhancing interfacial properties during subsequent film deposition.

Second, the etching rate can be precisely controlled. As confirmed in Experimental Examples 2, 3, and 6, the etching rate can be controlled by adjusting the process temperature and/or etchant supply amount, and self-limiting characteristics were exhibited where the EPC stabilizes after a certain number of cycles and reaches the saturation region when the etchant supply amount increases. This can solve the difficulty in controlling the etching rate that conventional highly reactive etchants such as hydrogen fluoride (HF) and hydrochloric acid (HCl) had, and means that precise thickness control at the atomic layer level is possible.

Third, reproducibility and uniformity of the process can be secured. As confirmed in Experimental Examples 3 and 6, since the etching reaction is maintained constant in the saturation region, high reproducibility can be secured as the etching amount does not vary greatly even with minute changes in process conditions. In addition, due to the self-limiting reaction characteristics, uniform etching is possible even in fine pattern processes with complex structures, preventing local etching concentration or non-uniformity.

Fourth, damage to lower regions can be minimized. The etchant of the present invention does not have the problem of penetrating into lower regions and causing damage like conventional etchants such as HCl and HF, and can precisely etch only desired regions through selective and controllable surface reactions. This can prevent deterioration of the electrical characteristics of devices and improve device reliability.

Fifth, it has versatility applicable to various metal nitride films. As confirmed in Experimental Example 7, effective etching is possible for various metal nitride films such as TiN, TiSiN, and MON, and the etching rate varies depending on the type of thin film, making it applicable to selective etching processes as well. This means that it can be widely utilized in various semiconductor device manufacturing processes.

In conclusion, it was confirmed that the thin film processing method of the present invention is an excellent technology that overcomes the limitations of the prior art and can simultaneously achieve precise thin film thickness control, surface roughness improvement, and process reproducibility required for manufacturing processes of miniaturized semiconductor devices.

### (6) Example 6 (Evaluation of Applicability to Various Transition Metal Films)

### Experimental Example 8

In order to confirm whether the thin film processing method of the present invention is applicable to various transition metal thin films, etching experiments were performed on oxide films and metal films having Group 4 metal elements (Ti, Hf), Group 5 metal elements (Nb, Ta), and Group 6 metal elements (Mo, W) as central elements.

Specifically, TiO, NbO, TaO, HfO oxide films and Mo, W metal films were prepared by depositing them on substrates respectively. For each thin film, O3 was used as a surface modifier and Dichloromethyl methyl ether was used as an etchant. The process temperature was set at 300° C., and according to the supply cycle shown in FIG. 2, the process of surface modifier supply-purge-etchant supply-purge was configured as one cycle and repeated until each thin film was sufficiently etched. Meanwhile, in the case of oxide films, the supply of the surface modifier can be omitted, and etching was performed using an etchant on the oxide films formed using an oxidizing agent.

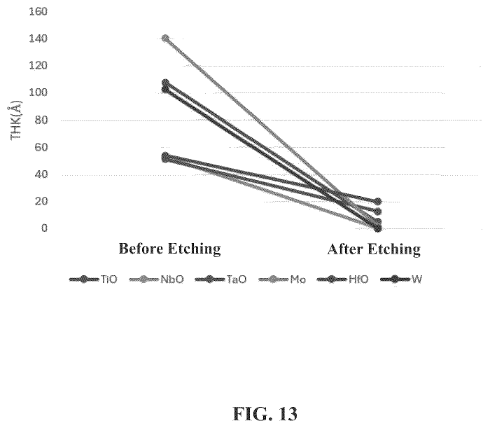

Table 1 below shows the thickness of thin films before/after etching, and FIG. 13 is a graph showing changes in thin film thickness according to etching.

TABLE 1

| | TiO | NbO | TaO | Mo | HfO | W |
|---|---|---|---|---|---|---|
| Before | 107.56 | 52.95 | 51.02 | 140.12 | 53.84 | 102.23 |
| Etching | | | | | | |
| After | 4.76 | 0 | 12.42 | 1.68 | 19.8 | 0 |
| Etching | | | | | | |

As shown in Table 1 and FIG. 13, it was confirmed that etching proceeded effectively in all transition metal thin films.

Specifically, in the case of Group 4 metal oxide films, TiO decreased by about 95.6% from an initial thickness of 107.56 Å to 4.76 Å and was almost completely etched, and HfO decreased by about 63.2% from an initial thickness of 53.84 Å to 19.8 Å.

In the case of Group 5 metal oxide films, NbO was completely etched from an initial thickness of 52.95 Å and decreased to 0 Å, and TaO decreased by about 75.7% from an initial thickness of 51.02 Å to 12.42 Å.

In the case of Group 6 metals, the Mo metal film decreased by about 98.8% from an initial thickness of 140.12 Å to 1.68 Å and was almost completely etched, and the W metal film was completely etched from an initial thickness of 102.23 Å and decreased to 0 Å.

As a result of visual confirmation through FIG. 13, it was confirmed that thin films that had considerable thickness before the process were greatly reduced or almost completely removed after the process in all thin films. In particular, NbO, Mo, and W showed that almost complete etching was possible, and other thin films also exhibited high etching rates.

Through these results, it was confirmed that the thin film processing method of the present invention can be effectively applied not only to metal nitride films but also to oxide films and metal films having various transition metals of Groups 4 to 6 as central elements. This demonstrates that the present invention is not limited to specific types of thin films and has versatility for a wide range of transition metal-based thin films.

In particular, it was confirmed that effective etching is also possible for metal films (Mo, W) through the combination of a surface modifier and an etchant. This shows that the method of the present invention is applicable not only to oxide films but also to pure metal films, and has high versatility that can be utilized for various thin film processing in semiconductor device manufacturing processes.

In conclusion, it was confirmed that the present invention is an excellent thin film processing technology capable of precise etching and surface treatment at the atomic layer level for a wide range of transition metal-based thin films including metal nitride films, metal oxide films, and metal films.

Features, structures, and effects described in the above-described exemplary embodiments are included in at least one exemplary embodiment of the present invention, but are not necessarily limited to only one exemplary embodiment. Furthermore, features, structures, and effects described in each embodiment can be combined or modified and implemented in other embodiments by one of ordinary skill in the art to which the embodiments belong. Therefore, it should be interpreted that contents related to such combinations and modifications are included in the scope of the present invention.

Further, while the present invention has been particularly described with reference to embodiments, the embodiments are only exemplary embodiments of the present invention and the present invention is not intended to be limited thereto. It will be understood by those skilled in the art that modifications and applications in other forms may be made without departing from the spirit and scope of the present invention. That is, each element specifically shown in the embodiments may be modified and embodied. In addition, it should be understood that differences related to these modifications and applications are within the scope of the present invention as defined in the appended claims.

What is claimed is:

1. A thin film processing method comprising:
supplying a surface modifier to an interior of a chamber in which a substrate having a thin film formed thereon is placed;
purging the interior of the chamber;
supplying an etchant to the interior of the chamber; and
purging the interior of the chamber,
wherein the etchant is represented by any one of the following <Formula 1>, <Formula 2>, and <Formula 3>: 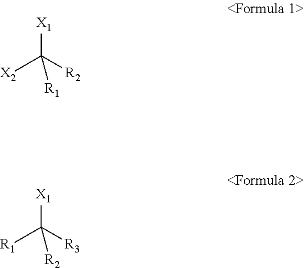
In the <Formula 1> or <Formula 2>, X1 to X2 may each be the same or different from each other, and are independently selected from hydrogen, chlorine element, and chloroalkyl group having 1 to 5 carbon atoms, R1 to R3 may each be the same or different from each other, and are independently selected from hydrogen, linear, branched, or cyclic alkyl group having 1 to 5 carbon atoms, aryl group having 6 to 12 carbon atoms, hydroxy group having 0 to 4 carbon atoms, and alkoxy group having 0 to 4 carbon atoms, and 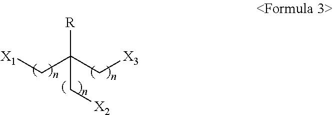
In the <Formula 3>, n is each independently selected from integers of 0 to 5, X1 to X3 are each independently selected from alkoxy group having 1 to 5 carbon atoms and dialkylamino group having 1 to 5 carbon atoms, and R is selected from hydrogen, linear, branched, or cyclic alkyl group having 1 to 5 carbon atoms, alkoxy group having 1 to 5 carbon atoms, and dialkylamino group having 1 to 5 carbon atoms.

2. The thin film processing method of claim 1, wherein the etchant is any one of Dichloromethyl methyl ether (DCMME), 1-chloromethyl ethyl ether (1-CMEE), Dimethylformamide dimethyl acetal (DFDA), and Tris(dimethylamino)methane (TDMAM).

3. The thin film processing method of claim 1, further comprising, before the step of supplying the surface modifier, forming the thin film on the substrate by Atomic Layer Deposition (ALD).

4. The thin film processing method of claim 1, wherein the thin film is a metal nitride thin film having a Group 4 metal as a central element.

5. The thin film processing method of claim 4, wherein the Group 4 metal is any one of Titanium (Ti), Zirconium (Zr), and Hafnium (Hf).

6. The thin film processing method of claim 1, wherein the thin film is a metal nitride thin film having a Group 5 metal as a central element.

7. The thin film processing method of claim 5, wherein the Group 5 metal is any one of Vanadium (V), Niobium (Nb), and Tantalum (Ta).

8. The thin film processing method of claim 1, wherein the thin film is a metal film or metal nitride thin film having a Group 6 metal as a central element.

9. The thin film processing method of claim 8, wherein the Group 6 metal is any one of Molybdenum (Mo) and Tungsten (W).

10. The thin film processing method of claim 1, wherein the surface modifier is any one of O₃, O₂, H₂O, and H₂O₂.

11. A method for manufacturing a memory device, comprising the thin film processing method according to claim 1.
